(19) United States
(12) Patent Application Publication
(10) Pub. No.: US 2005/0145479 A1
(43) Pub. Date: Jul. 7, 2005

(54) Method of coating a cutting tool

(75) Inventor: Lennart Karlsson, Fagersta (SE)

Correspondence Address: BURNS DOANE SWECKER & MATHIS L L P, POST OFFICE BOX 1404, ALEXANDRIA, VA, 22313-1404, US

(73) Assignee: SECO TOOLS AB, Fagersta (SE)

(21) Appl. No.: 11/017,638

(22) Filed: Dec. 22, 2004

(30) Foreign Application Priority Data
Dec. 22, 2003 (SE) 0303485-7

(51) Int. Cl. C23C 14/34

(52) U.S. Cl. 204/192.16; 204/192.15

(57) ABSTRACT

A method of depositing a nitride-based wear resistant layer on a cutting tool for machining by chip removal using reactive magnetron sputtering has a deposition rate, t_{d}, higher than 2 nm/s, a positive bias voltage, Vₛ, (with respect to ground potential) between +1 V and +60 V applied to the substrate, a substrate current density, Iₛ/Aₛ, larger than 10 mA/cm², a target surface area, Aₜ, larger than 0.7 times the substrate surface area, Aₛ, and a distance between the target surface and the substrate surface, dₜ, less than (Aₜ)^{0.5}.

### RELATED APPLICATION DATA

This application is based on and claims priority under 35 U.S.C. §119 to Swedish Application No. 0303485-7, filed Dec. 22, 2003, the entire contents of which are incorporated herein by reference.

### FIELD OF THE INVENTION

The present disclosure relates to a method of coating a cutting tool, aimed for machining by chip removal, with a hard and wear resistant nitride layer with low compressive stress. The method for deposition is characterized by the use of reactive magnetron sputtering using a substrate holder, whose projected area is small compared to the target area, and by a high electron density current through the substrate, obtained by applying a positive substrate bias.

### STATE OF THE ART

In the discussion of the state of the art that follows, reference is made to certain structures and/or methods. However, the following references should not be construed as an admission that these structures and/or methods constitute prior art. Applicant expressly reserves the right to demonstrate that such structures and/or methods do not qualify as prior art against the present invention.

The deposition of wear resistant PVD layers on a cutting tool can use substrate rotation to obtain the best possible coating thickness uniformity around the tool. However, this method can, at closer examination, be characterized as repeated periods of high deposition rate followed by longer periods without deposition or with low deposition rate, coating-off periods.

This periodic deposition rate can affect the coating properties in different ways. First, the average deposition rate decreases, which could act as a boost of the in-situ annealing for some coating material systems and therefore can reduce the intrinsic residual stress. Secondly, if the deposition rate is decreased too much, and no ultra high vacuum deposition system is used, the surface can be contaminated during the coating-off period due to adsorption, which in turn enhances the renucleation tendency. This means that commercial single layers are not true single layers but mostly multi-layer in the nanometer regime. This renucleation affects the coating properties in different ways, but will mostly increase the compressive residual stresses as well as the amount of inhomogeneous stresses.

Industrial use of thicker PVD MeN- and/or Me₂N-layers on cutting tools, has so far been strongly limited due to the compressive stresses normally possessed by such layers. The high biaxial compressive residual stress state at the cutting edge results in shear and normal stresses, which act as a pre-load of the coating. This pre-load, at a compressive biaxial stress state, decreases the effective adhesion of the coating to the substrate. When increasing the coating thickness, the shear and normal stress at the interface will increase. This effect is a limiting factor for the coating thickness of functional PVD-coatings.

Large efforts during the years have been made to develop PVD processes for deposition of thicker layers with a low compressive residual stress state. Different methods have been applied, such as use of low negative substrate bias (e.g., between −10 and −50 V), high substrate bias (e.g., −400V to −1000V), pulsed bias (e.g., unipolar and bipolar) as well as high pressure (e.g., above 5 Pa). However, none of these techniques is able to deposit a layer with low intrinsic compressive residual stress state with a maintained dense microstructure without induced defects caused by the rotation of the substrates.

Another approach to reduce the residual stress state, utilizing in-situ annealing during deposition, e.g., low deposition rate and/or high deposition temperature, has been tested without success.

U.S. Pat. No. 5,952,085 discloses a multiple layer erosion resistant coating on a substrate with alternate layers of tungsten and titanium diboride for gas turbine engines. All of the layers have the same thickness and preferably have thickness of between 0.3 and 1 micrometer to give improved erosion resistance. The deposition method of the layers uses magnetron sputtering with a positive bias.

EP-A-1245693 discloses low intrinsic residual stress coatings of TiB₂ grown by magnetron sputtering from a TiB₂ target.

### SUMMARY OF THE INVENTION

The present disclosure provides a method to grow wear resistant nitride layers with reduced compressive residual stress, preferably based on Al and/or Si and/or Cr, onto cutting tools for machining by chip removal.

The present disclosure also provides a method to grow wear resistant nitride layers as microstructurally true single layers with a good coating thickness distribution.

An exemplary method comprises forming a nitride-based wear resistant layer on a cutting tool by reactive magnetron sputtering. Parameters for reactive magnetron sputtering include: a deposition rate, td, higher than 2 nm/s, a positive bias voltage, Vₛ, between +1 V and +60 V applied to a substrate of the cutting tool, the positive bias voltage with respect to ground potential, a substrate current density, Iₛ/Aₛ, larger than 10 mA/cm², a ratio R=Aₜ/Aₛ greater than 0.7, where Aₜ is a target surface area and Aₛ is a substrate surface area, and a distance between a target surface and a substrate surface, dₜ, less than (Aₜ)^{0.5}.

An exemplary method comprises forming a nitride-based wear resistant layer on a cutting tool by reactive magnetron sputtering. Parameters for reactive magnetron sputtering include: a deposition rate, t_{d}, of 4 to 8 nm/s, a positive bias voltage, Vₛ, between +1 V and +60 V applied to a substrate of the cutting tool, the positive bias voltage with respect to ground potential, a substrate current density of 30 mA/cm² to 750 mA/cm², a ratio R=Aₜ/Aₛ greater than 0.7, where Aₜ is a target surface area and Aₛ is a substrate surface area, and a distance between a target surface and a substrate surface, dₜ, less than (Aₜ)^{0.5}.

### BRIEF DESCRIPTION OF THE DRAWINGS

The following detailed description of preferred embodiments can be read in connection with the accompanying drawings in which like numerals designate like elements and in which:

FIG. 1 is a schematic description of an exemplary embodiment of a deposition system, in which S is substrate holder, M is magnetron including target, P is vacuum pump, Vₜ target potential, Vₛ substrate bias (potential), Iₛ substrate current and Iₜ target current.

FIG. 2 shows schematically the definitions of target area, Aₜ, and substrate holder area, Aₛ.

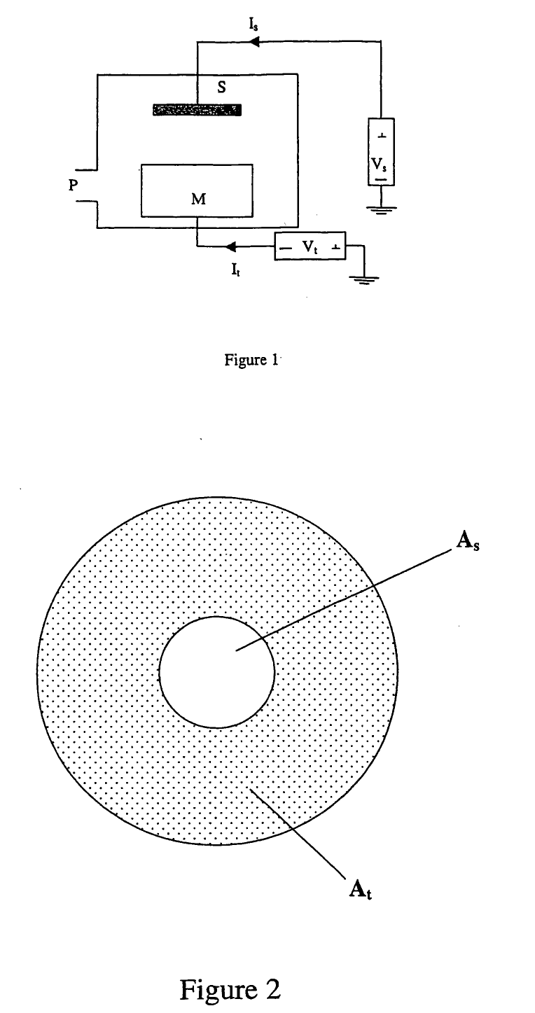

### DETAILED DESCRIPTION OF THE INVENTION

According to the present disclosure, there is provided a method for coating cutting tools for machining by chip removal. The cutting tool comprises a body of a hard alloy of cemented carbide, cermet, ceramics, cubic boron nitride-based material or high speed steel with a hard and wear resistant refractory coating. The wear resistant coating is composed of one or more layers of which at least one comprises a low compressive stress metal nitride layer deposited by reactive magnetron sputtering, i.e., MeN and/or Me₂N, where Me is one or more of the elements Sc, Y, Ti, Zr, Hf, V, Nb, Ta, Cr, Si, Al and B. The total amount of Al and/or Si and/or Cr is more about than 40% of the selected Me element, alternatively more than about 60%. B can optionally be included, replacing N content in some examples. The B content should, however, be less than about 10 at % of N and/or B. The remaining layer(s), if any at all, are composed of metal nitrides and/or carbides and/or oxides of elements chosen from Ti, Zr, Hf, V, Nb, Ta, Cr, W, Si and Al.

One feature of the method is that the ratio between the area of the target, Aₜ, and the area of the substrate holder facing the target, Aₛ, defined as R=Aₜ/Aₛ, is considerably larger than that commonly used in the process of depositing wear resistant coatings onto tools for machining by chip removal. For example, R>about 0.7, alternatively R>about 1.0, and alternatively R>about 1.5.

Another feature of the method is the distance from the target surface to the substrate surface, dₜ, is small, compared to the extension of the target. The value of the extension of the target can be approximated with the square root of the target area, such that the distance is dₜ<about (Aₜ)^{0.5} and alternatively dₜ<about 0.7*(Aₜ)^{0.5}. In this way it is possible to deposit coatings with good uniformity all around the tool without the use of substrate rotation. This method minimizes the amount of microstructural defects in the layers, which are induced during the coating-off periods, resulting in a coating with superior mechanical properties compared to coatings produced when rotating fixtures are used.

Since the area ratio, R, is large, a positive bias, Vₛ>0, can be used, which is not generally possible in industrial deposition. If this condition is not fulfilled, an extreme bias power supply is used and the plasma will be drained of electrons, which will stop the sputtering process. By applying a positive substrate bias, the deposition condition will change so that there will be a net electron current from the plasma to the substrate holder. This is different from the situation when a negative substrate bias is applied, which gives a net ion current from plasma to the substrate. Here, the electron current density φₛ=Iₛ/Aₛ is larger than 10 mA/cm² and preferably larger than 30 mA/cm². The high electron current density increases the surface mobility of atoms and thereby decreases the generation rate of lattice defects, which contribute to the compressive residual stress state in PVD coatings. By enhancing the surface mobility, layers with lower compressive residual stresses can be deposited. Also, the high electron current increases dissociation of the nitrogen molecules into atomic nitrogen. This effect minimizes the usual difficulties of achieving the correct stoichiometry of nitride coatings normally associated with reactive magnetron sputtering. In one exemplary embodiment of the disclosed method, nitrogen saturated nitride coatings are obtained in a wide range of nitrogen flow rates from 20 sccm (standard cubic centimeter per minute) up to more than 175 sccm at an Ar pressure of 0.25 Pa.

The use of a high area ratio R can result in a very low productivity and therefore an unrealistic high production cost. However, by depositing the coatings (unconventionally) close to the target surface, a very high deposition rate is obtained. This very high deposition rate when unconventionally close to the target lowers the production cost and makes the method economically profitable. The very high deposition rate, t_{d}, should be between about 2 and about 14 nm/s, alternatively between about 4 and about 8 nm/s. If the deposition rate is too high, e.g., greater than about 20 nm/s, the defect content of the layer will increase and this will be associated with an increased compressive residual stress state.

The average surface mobility of the elements can be adjusted in relation to the deposition rate of the process, i.e., at higher deposition rate, a higher surface mobility is used to maintain the stresses at a low level. The average surface mobility can be adjusted by, for example, increasing the bulk temperature and/or by adjusting the composition of the sputtered flux. When optimizing the composition, consideration shall also be made with respect to the mechanical properties of the final layer. In one example, a good surface atom mobility can be obtained with a composition of the sputtering target (and consequently of the sputtered flux) comprising Al and/or Si and/or Cr in an amount more than 40% of the selected Me element and alternatively more than 60%. B can optionally be included, replacing N content in some examples. If the composition includes B, the B content should, however, be less than 10 at % of N and/or B.

In one embodiment thick MeN and/or Me₂N-layers are deposited directly onto a cutting tool substrate as mentioned above. The thickness of each individual MeN and/or Me₂N layer then varies from about 5 μm to about 100 μm, alternatively from about 5 μm to about 50 μm, for metal machining when high wear resistance is desired.

In another embodiment, further layers of metal nitrides and/or carbides and/or oxides with metal elements selected from the group consisting of Ti, Nb, Hf, V, Ta, Mo, Zr, Cr, W and Al are deposited together with the MeN and/or Me₂N-layer. The total coating thickness then varies from about 5 μm to about 100 μm, alternatively from about 5 μm to about 50 μm, with the thickness of the non-MeN and/or -Me₂N layer(s) varying from about 0.1 μm to about 15 μm.

In yet another embodiment, thin layers (e.g., about 0.2-5 μm) with an increased effective adhesion can be deposited, using the disclosed method of deposition. Such layers can be used in applications where the demand on adhesion of the layer is particularly important. Examples of layers with increased effective adhesion include layers having compositions comprising, e.g., (Ti,Al)N, (Ti,Al,Cr)N, (Al,Cr)N, (Ti,Al,Si)N, (Ti,Al,Cr, Si)N, (Ti,Si)N, and/or (Cr, Si)N.

According to embodiments of the method, a low compressive stress nitride layer, e.g. MeN and/or Me₂N layers, are deposited by reactive magnetron sputtering using the following characteristics:
Magnetron power density: 3.1 W/cm² to 63 W/cm², alternatively 9.4 W/cm² to 19 W/cm².
Substrate current density Iₛ/Aₛ: >10 mA/cm², alternatively 10 mA/cm² to 1500 mA/cm², alternatively 30 mA/cm² to 750 mA/cm².
Atmosphere: mixture of Ar and N₂ or pure N₂
Total pressure: <5 Pa
Bias voltage Vₛ: >0, alternatively >+5 V but <+60 V.
Geometrical arrangements:
   Target area to substrate area: R=Aₜ/Aₛ: R>0.7, alternatively >1.0, and alternatively >1.5
   Target to substrate distance: dₜ<(Aₜ)^{0.5}, alternatively dₜ<0.7*(Aₜ)^{0.5}, and alternatively dₜ<0.5(Aₜ)^{0.5}

The sputtering target preferably contains more than 40 at % Al and/or Si and/or Cr and/or B, more preferably more than 60 at %. If the composition of the sputtering target includes B, the B content should, however, be less than 10 at %.

Without being limited to any particular theory, it is believed that the advantage of the presently disclosed deposition method is due to a combination of several effects. For example, some of the effects include:
The area relation between the target and the substrate holder, in combination with the close distance from the target to the substrate, gives an advantage of a high deposition rate with good coating thickness uniformity around the tool in the absence of coating-off periods. This gives a coating with minimized amount of microstructural defects, interlayers and re-nucleation zones, caused by residual gases.
The area relation between the target and the substrate holder makes it possible to use a positive substrate bias. The positive substrate bias gives three-fold advantage due to the high electron current density; including, increased surface mobility of adatoms minimizes the microstructural defects and thereby the compressive residual stress; increased dissociation rate of nitrogen molecules into atomic nitrogen makes it easier to achieve desired stoichiometric composition of the layer; and Increased desorption rate of absorbed hydrogen and/or water molecules from the surface would decrease the formation rate of hydroxide based defect complex, which contribute to high compressive stresses in some coating material systems.
By using a target composition that is tailored for a high surface mobility of the adatoms, the associated risk of high compressive stress due to the high deposition rate is minimized.

Although described with reference to a reactive magnetron sputtering method for deposition of MeN and/or Me₂N layer(s), it is obvious that the disclosed exemplary methods can also be applied to the deposition of other coating material based on metal carbonitrides and/or carbooxynitrides and/or oxynitrides with the metal elements chosen from Ti, Zr, Hf, V, Nb, Ta, Cr, W, Si and Al by adding carbon and/or oxygen containing gas.

### EXAMPLE 1

(Ti,Al)N-layers were deposited in a deposition system equipped with a rectangular dc magnetron sputter source with a Ti+Al target (50 at % Ti+50 at % Al) of 318 cm². The substrate table projected surface area was 20 cm² positioned at a distance of 5 cm from the target surface.

Mirror-polished cemented carbide substrates with composition 6 wt % Co and 94 wt % WC were used. The WC grain size was about 1 μm and the hardness was 1650 HV₁₀.

Before deposition, the substrates were cleaned in an ultrasonic bath of an alkali solution and in alcohol. The substrates were stationarily positioned above the magnetron and resistively heated by an electron beam for 40 min to about 400° C. Immediately after heating, the substrates were argon-ion etched (ion current density 5 mA/cm²) for 30 minutes using a substrate bias of −200V. The subsequent (Ti,Al)N deposition was carried out by reactive magnetron sputtering using a magnetron power of 5 kW, an Ar pressure of 0.3 Pa, a nitrogen flow rate of 100 sccm. The substrate bias voltages, Vₛ, were varied in three different deposition processes: −100V, −50V and +50V. The resulting thickness of the positively biased layers was ˜5 μm after 20 min of deposition corresponding to a deposition rate of 4,2 nm/s. The substrate temperature was measured with a thermocouple attached to the substrate holder. The temperatures were approximately 400° C. (using negative bias) to 500° C. (using positive bias) at the end of the reactive deposition period.

The substrate current Iₛ was +1.2 A for negative Vₛ, irrespective of voltage. When changing from negative to positive Vₛ the substrate current changed sign from positive to negative and become around −10 A corresponding to electron current of 500 mA/cm².

XRD analysis showed that all layers exhibited the cubic sodium chloride structure (Ti,Al)N with a lattice parameter of about 4.18 Å.

By applying a positive Vₛ, a layer with low compressive residual stress states, σₜₒₜ≈+0.6 GPa, was obtained measured using the XRD sin ²φ method. The thermal stresses, σ_{Thermal}, can be calculated using

$${σ}_{thermal} = \frac{{E}_{f}}{( 1 - {v}_{f} )} \cdot ( {α}_{f} - {α}_{sub} ) \cdot ( {T}_{dep} - {T}_{ana} ) \qquad Eq . 1$$

where E_{f} and ν_{f} are the Young's modulus and Poisson's ratio of the layer, respectively, α_{f} and α_{sub} are the coefficient of thermal expansion of the layer and substrate material, respectively, and T_{dep} and Tₐₙₐ are the deposition temperature and analysis temperature, respectively, in K. Using α_{sub}=4.8*10⁻⁶, α_{(Ti,Al)N,a}=9.35*10⁻⁶, E_{f}=450 GPa, ν_{f}=0.22, T_{dep}=773 K, Tₐₙₐ=298 K in the equation above gives σₜₕₑᵣₘₐₗ=+1.2 GPa. The intrinsic stress can then be obtained by applying the equation:
σᵢₙₜ=σₜₒₜ−σₜₕₑᵣₘₐₗ Eq. 2

The intrinsic stress, σᵢₙₜ, of coatings deposited with positive bias is therefore: σᵢₙₜ=+0.6−1.2=−0.6 GPa, i.e., those coatings are grown in a low compressive intrinsic stress mode. Using negative Vₛ gave layers with total residual stresses in the range of approximately −2 GPa.

Adhesion testing by Rockwell indentation revealed that the adhesion was acceptable for all layers. Table 1 summarizes some results for four samples. There was no significant difference in adhesion between variant A and D, but since D, an example of the present invention, has almost three times thicker coating the results are extremely good. The indentation test demonstrates that the layer deposited according to the present methods has strongly enhanced toughness properties compared to layers grown using negative bias and state of the art.

TABLE 1
Properties of the (Ti, Al)N layers.

| | | | Coating | | |
|---|---|---|---|---|---|
| | Vₛ | Deposition | Thickness | | σ [GPa] |
| Variant | [V] | Rate (nm/s) | [um] | HR_{C} | Total |
| A | Prior art | 0.8 | 2.4 | Good | −3.8 |
| B | −100 V | 4.3 | 5.1 | Acceptable | −2.1 |
| C | −50 V | 4.5 | 5.4 | Acceptable | −1.7 |
| D | +50 V | 5.1 | 6.1 | Good | +0.6 |
| Present | | | | | |
| invention | | | | | |

### EXAMPLE 2

In order to determine the N₂ flow rate to obtain a stoichiometric ratio between the metallic elements and nitrogen, i.e., (Ti+Al)/N˜1, a test was performed where the N₂ flow rate was varied between 10 and 175 sccm. All other deposition data was kept constant, e.g., the magnetron power at 5 kW, the substrate bias at +50V, Ar pressure at 0.25 Pa. The deposition system set-up was the same as in Example 1. The content of Al, Ti and N in the layers was measured using EDS. The results are reported in Table 2 below and show that using the present methods a surprisingly high stability for the N₂ flow rate is achieved. In the whole range between 30 sccm and 175 sccm, a stoichiometric composition is obtained, e.g., (Ti+Al)/N is about 1. This is an effect of the high substrate electron current, increasing the dissociation rate of the N₂ molecule. No Ar was detected in any of the layers.

TABLE 2
Dependence of stoichiometry ratio (Ti + Al)/N on N₂ flow rate

| | N₂ flow rate | Ti | Al | N | Stoichiometry |
|---|---|---|---|---|---|
| Variant | [sccm] | [at %] | [at %] | [at %] | ratio (Ti + Al)/N |
| E | 10 | 41 | 40 | 19 | 4.40 |
| F | 20 | 33 | 32 | 35 | 1.85 |
| G | 30 | 24 | 27 | 50 | 1.02 |
| H | 40 | 24 | 26 | 49 | 1.03 |
| I | 50 | 24 | 28 | 48 | 1.09 |
| J | 75 | 26 | 26 | 48 | 1.08 |
| K | 100 | 25 | 27 | 47 | 1.11 |
| L | 125 | 23 | 26 | 50 | 0.98 |
| M | 150 | 23 | 26 | 51 | 0.95 |
| N | 175 | 23 | 26 | 51 | 0.95 |

### EXAMPLE 3

Cemented carbide cutting tool inserts from Example 1 (the same names of the variants are used) were used in a face milling cutting test, in solid and slotted work piece material, SS2541. The homogeneous cutting test (solid work piece) was made in a 60 mm wide plate and the interrupted cutting test was performed by using three 20 mm wide plates separated by 10 mm, mounted as a package. The cutting data were; v_{c}=250 m/min (homogeneous) and 200 m/min (interrupted), f=0.1 mm/rev and depth of cut=2.5 mm.

TABLE 3
Face Milling Cutting Test

| | | Homogeneous cut | Interrupted cut |
|---|---|---|---|
| Variant | | Tool life, mm | Tool life, mm |
| A | Prior art (Ti, Al)N | 2200 | 1500 |
| B | (Ti, Al)N | 1700 | 900 |
| | (Vₛ = −100 V) | | |
| D | Present invention | 2800 | 2100 |
| | (Ti, Al)N | | |
| | (Vₛ = +50 V) | | |

This test demonstrates that the variant D shows the best wear resistance, but also surprisingly the best toughness in spite of the thickest coating.

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

1. A method comprising:
forming a nitride-based wear resistant layer on a cutting tool by reactive magnetron sputtering, wherein parameters for reactive magnetron sputtering include:
a deposition rate, t_{d}, higher than 2 nm/s,
a positive bias voltage, Vₛ, between +1 V and +60 V applied to a substrate of the cutting tool, the positive bias voltage with respect to ground potential,
a substrate current density, Iₛ/Aₛ, larger than 10 mA/cm²,
a ratio R=Aₜ/Aₛ greater than 0.7, where Aₜ is a target surface area and Aₛ is a substrate surface area, and
a distance between a target surface and a substrate surface, dₜ, less than (Aₜ)^{0.5}

2. The method according to claim 1, wherein the cutting tool is a cutting tool for machining by chip removal.

3. The method according to claim 1, wherein R is greater than 1.0 and dₜ is less than 0.7*(Aₜ)^{0.5}.

4. The method according to claim 1, wherein R is greater than 1.5 and dₜ is less than 0.5*(At)^{0.5}

5. The method according to claim 1, wherein the substrate current density, Iₛ/Aₛ, is larger than 30 mA/cm².

6. The method according to claim 1, wherein the deposition rate, t_{d}, is higher than 3 nm/s.

7. The method according to claim 1, wherein in the nitride-based wear resistant layer is MeN and/or Me₂N, where Me is one or more of the elements Sc, Y, Ti, Zr, Hf, V, Nb, Ta, Cr, Si, Al and B.

8. The method according to claim 1, wherein the nitride layer contains a total amount of Al and/or Si and/or Cr of more than about 40% of the selected Me element.

9. The method according to claim 8, wherein up to 10 at % of N is replaced by B.

10. The method according to claim 1, wherein the deposition rate is less than 14 nm/s.

11. A method comprising:
forming a nitride-based wear resistant layer on a cutting tool by reactive magnetron sputtering, wherein parameters for reactive magnetron sputtering included:
a deposition rate, t_{d}, of 4 to 8 nm/s,
a positive bias voltage, Vₛ, between +1 V and +60 V applied to a substrate of the cutting tool, the positive bias voltage with respect to ground potential,
a substrate current density of 30 mA/cm² to 750 mA/cm²,
a ratio R=Aₜ/Aₛ greater than 0.7, where Aₜ is a target surface area and Aₛ is a substrate surface area, and
a distance between a target surface and a substrate surface, dₜ, less than (Aₜ)^{0.5}.

12. The method according to claim 11, the cutting tool is a cutting tool for machining for chip removal.

13. The method according to claim 11, wherein R is greater than 1.0 and dₜ is less than 0.7*(At)^{0.5}.

14. The method according to claim 11, wherein in the nitride-based wear resistant layer is MeN and/or Me₂N, where Me is one or more of the elements Sc, Y, Ti, Zr, Hf, V, Nb, Ta, Cr, Si, Al and B.
